(19) United States
(12) Patent Application Publication
(10) Pub. No.: US 2026/0136572 A1
(43) Pub. Date: May 14, 2026

(54) MANUFACTURING METHOD OF SEMICONDUCTOR DEVICE

(71) Applicant: FUJI ELECTRIC CO., LTD., Kanagawa (JP)

(72) Inventor: Yasuyuki HOSHI, Matsumoto-city (JP)

(21) Appl. No.: 19/334,921

(22) Filed: Sep. 21, 2025

(30) Foreign Application Priority Data
Nov. 12, 2024 (JP) 2024-197754

(51) Int. Cl. H10D 12/01; H10D 12/00; H10D 62/10; H10D 64/23

(52) U.S. Cl. CPC H10D 12/035; H10D 12/481; H10D 62/109; H10D 62/127; H10D 64/232

(57) ABSTRACT

Provided is a manufacturing method including: forming a contact trench in a mesa portion; forming a contact dielectric film on a side wall and a bottom surface of the contact trench; etching a part of the contact dielectric film to expose a first emitter portion on the side wall of the contact trench and to expose a region of a second conductivity type on the bottom surface of the contact trench; and filling an inside of the contact trench with a conductive material to bring the conductive material into contact with the first emitter portion and the region of the second conductivity type.

The contents of the following patent application(s) are incorporated herein by reference:
NO. 2024-197754 filed in JP on Nov. 12, 2024.

### BACKGROUND

### 1. Technical Field

The present invention relates to a manufacturing method of a semiconductor device.

### 2. Related Art

Paragraph 0119 of Patent Document 1 describes that “in the present example, the doping concentration of the P type diffusion region 16 is higher than the doping concentration of the P type base region 14. The P type diffusion region 16 may have a concentration peak having a doping concentration higher than that of the P type base region 14. In order to form the P type diffusion region 16, it is preferable to perform ion implantation obliquely”. Paragraph 0040 of Patent Document 2 discloses “performing the first oblique ion implantation 32 at a shallow depth d1 with respect to the side wall 8b of the contact trench 8”. Paragraph 0021 of Patent Document 3 discloses that “the side wall of the body contact trench (second trench) 8 has an inclined portion that connects the vicinity of the upper end portion of the first trench 4 and the bottom portion of the body contact trench (second trench) 8 located deeper than the upper surface of the gate electrode”. Paragraph 0075 of Patent Document 4 describes that “the contact trench 52 is formed deeper than the p well region 26. The contact trench 52 is formed such that a first inclination angle (“θ1” in FIG. 3) of the side surface of the contact trench 52 with respect to the first surface is 60 degrees or more and 85 degrees or less”. Paragraph 0048 of Patent Document 5 describes that “the source region 104 includes a first source subregion 1041 directly adjacent to the contact 112 in the source contact zone 113 of the first surface 110. The source region 104 further includes a second source subregion 1042 and a third source subregion 1043”.
Patent Document 1: Japanese Patent Application Publication No. 2023-128635
Patent Document 2: Japanese Patent Application Publication No. 2018-110166
Patent Document 3: Japanese Patent Application Publication No. 2011-134985
Patent Document 4: Japanese Patent Application Publication No. 2018-14455
Patent Document 5: Japanese Patent Application Publication No. 2020-145430

### BRIEF DESCRIPTION OF THE DRAWINGS

FIG. 1 is a top view illustrating an example of a semiconductor device 100.

FIG. 2 is an example of an enlarged view of a region D in FIG. 1.

FIG. 3 is a view illustrating an example of a cross section taken along line a-a in FIG. 2.

FIG. 4 is an enlarged view of a cross section in a vicinity of a mesa portion 60.

FIG. 5 is a view illustrating an example of a doping concentration distribution taken along line h-h in FIG. 4.

FIG. 6 is a view illustrating another example of the doping concentration distribution taken along line h-h.

FIG. 7 is a view illustrating another example of the doping concentration distribution taken along line h-h.

FIG. 8 is a view illustrating a partial process of a manufacturing process of the semiconductor device 100.

FIG. 9 is a view illustrating a partial process of the manufacturing process of the semiconductor device 100.

FIG. 10 is a view illustrating an example of collector voltage-collector current characteristics of the semiconductor device 100.

### DESCRIPTION OF EXEMPLARY EMBODIMENTS

The present invention will be described below through embodiments of the invention, but the following embodiments do not limit the invention according to the claims. In addition, not all combinations of features described in the embodiments are essential to a solution of the invention.

In the present specification, one side in a direction parallel to a depth direction of a semiconductor substrate is referred to as “upper” and another side is referred to as “lower”. One surface of two principal surfaces of a substrate, a layer or another member is referred to as an upper surface, and another surface is referred to as a lower surface. “Upper” and “lower” directions are not limited to a direction of gravity, or a direction in implementation of a semiconductor device.

In the present specification, technical matters may be described by using orthogonal coordinate axes of an X axis, a Y axis, and a Z axis. The orthogonal coordinate axes merely specify relative positions of components, and do not limit a particular direction. For example, the Z axis is not limited to indicate a height direction with respect to the ground. It is to be noted that a +Z axis direction and a −Z axis direction are directions opposite to each other. When a Z axis direction is described without describing a sign, it means that the direction is parallel to a +Z axis and a −Z axis.

In the present specification, orthogonal axes parallel to the upper surface and the lower surface of the semiconductor substrate are referred to as the X axis and the Y axis. In addition, an axis perpendicular to the upper surface and the lower surface of the semiconductor substrate is referred to as the Z axis. In the present specification, a direction of the Z axis may be referred to as the depth direction. In addition, in the present specification, a direction parallel to the upper surface and the lower surface of the semiconductor substrate may be referred to as a horizontal direction, including an X axis direction and a Y axis direction.

A region from a center of the semiconductor substrate in the depth direction to the upper surface of the semiconductor substrate may be referred to as an upper surface side. Similarly, a region from the center of the semiconductor substrate in the depth direction to the lower surface of the semiconductor substrate may be referred to as a lower surface side.

In the present specification, a case where a term such as “same” or “equal” is mentioned may include a case where an error due to a variation in manufacturing or the like is included. The error is, for example, within 10%.

In the present specification, a conductivity type of a doping region where doping has been carried out with an impurity is described as a p type or an n type. In the present specification, the impurity may particularly mean either a donor of the n type or an acceptor of the p type, and may be described as a dopant. In the present specification, doping means introducing the donor or the acceptor into the semiconductor substrate and turning it into a semiconductor presenting a conductivity type of the n type, or a semiconductor presenting a conductivity type of the p type.

In the present specification, a doping concentration means a concentration of the donor or a concentration of the acceptor in a thermal equilibrium state. In the present specification, a net doping concentration means a net concentration obtained by adding the donor concentration set as a positive ion concentration to the acceptor concentration set as a negative ion concentration, taking into account of polarities of charges. As an example, when the donor concentration is N_{D} and the acceptor concentration is N_{A}, the net doping concentration at any position is given as N_{D}-N_{A}. In the present specification, the net doping concentration may be simply referred to as the doping concentration.

The donor has a function of supplying electrons to a semiconductor. The acceptor has a function of receiving electrons from the semiconductor. The donor and the acceptor are not limited to the impurities themselves. For example, a VOH defect in which a vacancy (V), oxygen (O), and hydrogen (H) present in the semiconductor are attached together functions as the donor which supplies the electrons. In the present specification, the VOH defect may be referred to as a hydrogen donor.

In the present specification, a description of a P+ type or an N+ type means a higher doping concentration than that of the P type or the N type, and a description of a P− type or an N− type means a lower doping concentration than that of the P type or the N type. In the present specification, a conductivity type indicated by lowercase p or n, such as the p type or the n type, does not indicate a relative magnitude of the doping concentration. In the present specification, a unit system is an SI unit system unless otherwise noted. Although a unit of a length may be expressed in cm, various calculations may be performed after conversion to meters (m).

A chemical concentration in the present specification refers to an atomic density of an impurity measured regardless of an electrical activation state. The chemical concentration (atomic density) can be measured by, for example, secondary ion mass spectrometry (SIMS). The net doping concentration described above can be measured by capacitance-voltage profiling (CV profiling). In addition, a carrier concentration measured by spreading resistance profiling (SRP method) may be set as the net doping concentration. The carrier concentration measured by the CV profiling or the SRP method may be a value in a thermal equilibrium state. In addition, in a region of the n type, the donor concentration is sufficiently higher than the acceptor concentration, and thus the carrier concentration of the region may be set as the donor concentration. Similarly, in a region of the p type, the carrier concentration of the region may be set as the acceptor concentration. In the present specification, the doping concentration of the n type region may be referred to as the donor concentration, and the doping concentration of the p type region may be referred to as the acceptor concentration.

When a concentration distribution of the donor, acceptor, or net doping has a peak in a region, a value of the peak may be defined as the concentration of the donor, acceptor, or net doping in the region. In a case where the concentration of the donor, acceptor or net doping is substantially uniform in a region, or the like, an average donor, acceptor or net doping concentration in the region may be defined as a donor, acceptor or net doping concentration. In the present specification, atoms/cm³ or /cm³ is used to express a concentration per unit volume. This unit is used for the donor or acceptor concentration or the chemical concentration in the semiconductor substrate. A notation of atoms may be omitted.

The carrier concentration measured by the SRP method may be lower than the concentration of the donor or the acceptor. In a range where a current flows when a spreading resistance is measured, carrier mobility of the semiconductor substrate may be lower than a value in a crystalline state. The reduction in the carrier mobility occurs when carriers are scattered due to disorder of a crystal structure due to a lattice defect or the like.

The concentration of the donor or the acceptor calculated from the carrier concentration measured by the CV profiling or the SRP method may be lower than a chemical concentration of an element indicating the donor or the acceptor. As an example, in a silicon semiconductor, a donor concentration of phosphorous or arsenic serving as a donor, or an acceptor concentration of boron serving as an acceptor is approximately 99% of chemical concentrations of these. On the other hand, in the silicon semiconductor, a donor concentration of hydrogen serving as a donor is approximately 0.1% to 10% of a chemical concentration of hydrogen. Each concentration in the present specification may be a value at room temperature. As an example, a value at 300K (Kelvin) (substantially 26.9 degrees C.) may be used for a value at room temperature.

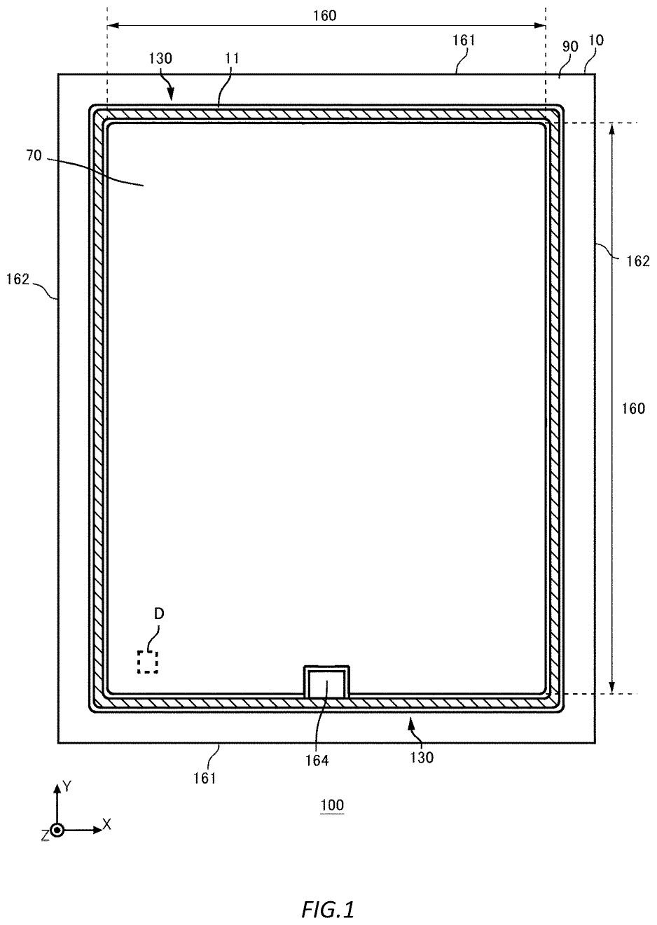

FIG. 1 illustrates a top view illustrating an example of a semiconductor device 100. FIG. 1 illustrates a position at which each member is projected on an upper surface of a semiconductor substrate 10. FIG. 1 illustrates only some members of the semiconductor device 100, and illustration of some members is omitted.

The semiconductor device 100 includes the semiconductor substrate 10. The semiconductor substrate 10 is a substrate which is formed of a semiconductor material. Although the semiconductor substrate 10 is a silicon substrate by way of example, the material of the semiconductor substrate 10 is not limited to silicon. The semiconductor substrate 10 may be a wide band gap substrate formed of a material having a band gap larger than that of silicon. For example, the semiconductor substrate 10 may be a compound semiconductor substrate such as a SiC substrate or a GaN substrate.

The semiconductor substrate 10 has a first end side 161 and a second end side 162 in a top view. In the present specification, unless otherwise specified, a top view means a view from the upper surface side of the semiconductor substrate 10. The semiconductor substrate 10 of the present example has two sets of first end sides 161 facing each other in a top view. In addition, the semiconductor substrate 10 of the present example has two sets of second end sides 162 facing each other in a top view. In FIG. 1, the first end side 161 is parallel to the X axis direction. The second end side 162 is parallel to the Y axis direction. In addition, the Z axis is perpendicular to the upper surface of the semiconductor substrate 10. In addition, the first end sides 161 are perpendicular to an extending direction or a longitudinal direction of a gate trench portion which will be described below. The second end sides 162 are parallel to the extending direction or the longitudinal direction of the gate trench portion which will be described below.

The semiconductor substrate 10 is provided with an active portion 160. The active portion 160 is a region where a main current flows in the depth direction between the upper surface and a lower surface of the semiconductor substrate 10 when the semiconductor device 100 operates. An emitter electrode is provided above the active portion 160, but illustration thereof is omitted in FIG. 1.

In the present example, the active portion 160 is provided with a transistor portion 70 including a transistor element such as an IGBT. In another example, the transistor portion 70 and a diode portion including a diode element such as a free wheel diode (FWD) may be alternately arranged along a predetermined array direction on the upper surface of the semiconductor substrate 10. Although one transistor portion 70 is provided in the present example, a plurality of transistor portions 70 may also be provided. A well region of the P+ type or a gate runner may be provided between the transistor portions 70.

The transistor portion 70 includes a collector region of the P+ type in a region in contact with the lower surface of the semiconductor substrate 10. In addition, in the transistor portion 70, an emitter region of the N+ type, a base region of the P− type, a drift region of the N− type, and a surface MOS structure having a gate conductive portion, and a gate dielectric film are periodically arranged on the upper surface side of the semiconductor substrate 10.

The semiconductor device 100 may include one or more pads above the semiconductor substrate 10. The semiconductor device 100 of the present example includes a gate pad 164. The semiconductor device 100 may include a pad such as an anode pad, a cathode pad, and a current detection pad. Each pad is arranged in a vicinity of the first end side 161. The vicinity of the first end side 161 refers to a region between the first end side 161 and the emitter electrode in a top view. In implementation of the semiconductor device 100, each pad may be connected to an external circuit via a wiring such as a wire.

A gate potential is applied to the gate pad 164. The gate pad 164 is electrically connected to a conductive portion of a gate trench portion of the active portion 160. The semiconductor device 100 includes a gate wiring line 130 that connects the gate pad 164 and the gate trench portion. In FIG. 1, the gate wiring line 130 is hatched with diagonal lines.

The gate wiring line 130 is arranged between the active portion 160 and the first end side 161 or the second end side 162 in a top view. The gate wiring line 130 of the present example encloses the active portion 160 in a top view. A region enclosed by the gate wiring line 130 in a top view may be the active portion 160. In addition, the gate wiring line 130 is connected to the gate pad 164. The gate wiring line 130 is arranged above the semiconductor substrate 10. The gate wiring line 130 may be a metal wiring including aluminum or the like. The gate wiring line 130 may be provided separate from the emitter electrode.

A p type outer circumferential well region 11 is provided so as to overlap the gate wiring line 130. That is, similarly to the gate wiring line 130, the p type outer circumferential well region 11 encloses the active portion 160 in a top view. The p type outer circumferential well region 11 is provided so as to extend with a predetermined width also in a range not overlapping the gate wiring line 130. The p type outer circumferential well region 11 is a region of a second conductivity type. The p type outer circumferential well region 11 of the present example is of the P+ type. A doping concentration of the p type outer circumferential well region 11 may be 5.0×10¹⁷ atoms/cm³ or more and 5.0×10¹⁹ atoms/cm³ or less. The doping concentration of the p type outer circumferential well region 11 may be 2.0×10¹⁸ atoms/cm³ or more and 2.0×10¹⁹ atoms/cm³ or less.

The semiconductor device 100 may include a temperature sensing unit (not illustrated) which is a pn junction diode formed of polysilicon or the like, and a current detection unit (not illustrated) which simulates an operation of the transistor portion 70 provided in the active portion 160. The temperature sensing unit may be connected to the anode pad and the cathode pad via a wiring. When the temperature sensing unit is provided, the temperature sensing unit is preferably provided at a center of the semiconductor substrate 10 in the X axis direction and the Y axis direction.

The semiconductor device 100 of the present example includes an edge termination structure portion 90 between the active portion 160 and the first end side 161 or the second end side 162 in a top view. The edge termination structure portion 90 of the present example is arranged between the outer circumferential gate wiring line 130 and the first end side 161 or the second end side 162. The edge termination structure portion 90 reduces electric field strength on the upper surface side of the semiconductor substrate 10. The edge termination structure portion 90 may include at least one of a guard ring, a field plate, or a RESURF which are annularly provided enclosing the active portion 160.

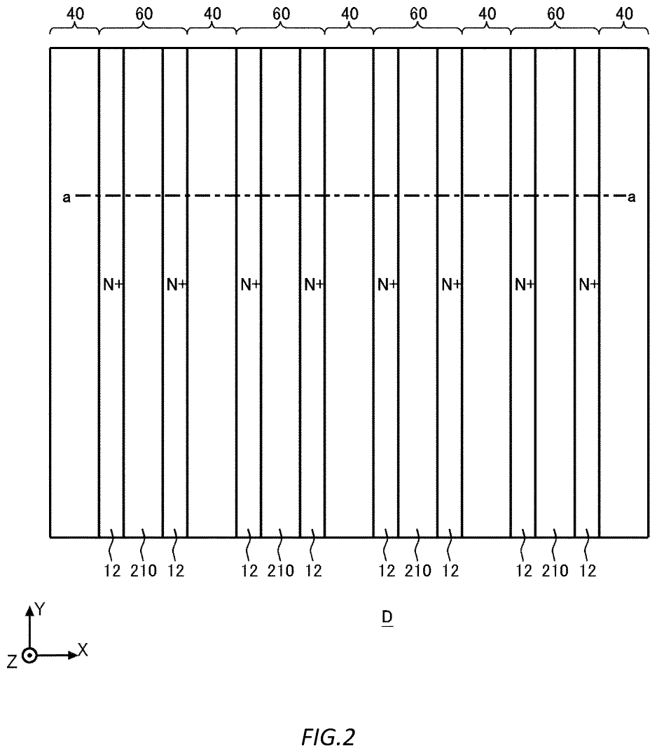

FIG. 2 is an example of an enlarged view of a region D in FIG. 1. The region D is a region which includes the transistor portion 70 of the active portion 160 illustrated in FIG. 1. FIG. 2 illustrates a structure of the upper surface of the semiconductor substrate 10 in the region D. In the region D, the semiconductor device 100 includes a plurality of gate trench portions 40 and a plurality of mesa portions 60.

The plurality of gate trench portions 40 are provided side by side in a first direction at the upper surface of the semiconductor substrate 10. The first direction of the present example is the X axis direction. The gate trench portions 40 are arrayed at predetermined intervals in the X axis direction. Each gate trench portion 40 is provided at the upper surface of the semiconductor substrate 10 to extend in a second direction intersecting the first direction. That is, the gate trench portion 40 is elongated in the second direction at the upper surface of the semiconductor substrate 10. The second direction of the present example is the Y axis direction. Each gate trench portion 40 is provided from the upper surface to an inside of the semiconductor substrate 10.

The gate trench portion 40 is a trench portion to which a gate potential is applied. A gate conductive portion formed of a conductive material such as polysilicon is arranged inside the gate trench portion 40. The gate conductive portion is electrically connected to the gate wiring line 130 (see FIG. 1), and a predetermined gate voltage is applied thereto. A part of the gate trench portion 40 illustrated in FIG. 2 may be replaced with a dummy trench portion. The dummy trench portion is a trench portion to which a potential of the emitter electrode is applied. The dummy trench portion has a structure similar to that of the gate trench portion. A trench portion adjacent to the gate trench portion 40 in the X axis direction may be the dummy trench portion. One or more dummy trench portions may be arranged between two gate trench portions 40. However, the gate trench portions 40 may be arranged adjacent to each other in the X axis direction.

A region of the semiconductor substrate 10 sandwiched between two trench portions in the X axis direction is defined as a mesa portion 60. Each end of the mesa portion 60 in the X axis direction is a boundary portion with each trench portion. A depth position of a lower end of the mesa portion 60 is to be the same as a depth position of a lower end of at least one of the trench portions on both sides.

An emitter region 12 and a trench contact portion 210 are provided in at least one mesa portion 60. The emitter region 12 and the trench contact portion 210 may be provided in at least one mesa portion 60 in contact with the gate trench portion 40, the emitter region 12 and the trench contact portion 210 may be provided in all mesa portions 60 in contact with the gate trench portion 40, or the emitter region 12 and the trench contact portion 210 may be provided in all mesa portions 60.

The emitter region 12 is a region of the N+ type provided to be exposed on the upper surface of the semiconductor substrate 10. The emitter region 12 of the present example is in contact with the gate trench portion 40. Each emitter region 12 may have a band shape extending in the Y axis direction. The emitter region 12 may be provided in each of the gate trench portions 40 sandwiching the mesa portion 60. In a portion in contact with the gate trench portion 40, one emitter region 12 extending in the Y axis direction may be provided in one mesa portion 60. In another example, a plurality of emitter regions 12 discretely arranged in the Y axis direction may be provided in a portion in contact with the gate trench portion 40. In this case, a contact region of the P+ type may be provided between two emitter regions 12 in the Y axis direction. That is, the emitter region 12 and the contact region may be alternately arranged in the Y axis direction.

The trench contact portion 210 is provided from the upper surface to the inside of the semiconductor substrate 10 in the mesa portion 60. The trench contact portion 210 may be provided at the upper surface of the semiconductor substrate 10 to extend in the Y axis direction. That is, the trench contact portion 210 may be elongated in the Y axis direction at the upper surface of the semiconductor substrate 10. The trench contact portion 210 has a structure in which a trench provided in the mesa portion 60 is filled with a conductive material. An emitter potential is applied to the conductive material. The trench contact portion 210 is not in contact with the trench portion. In the present example, the emitter region 12 is provided between the trench contact portion 210 and the trench portion. The above-described contact region may also be provided in a partial region between the trench contact portion 210 and the trench portion.

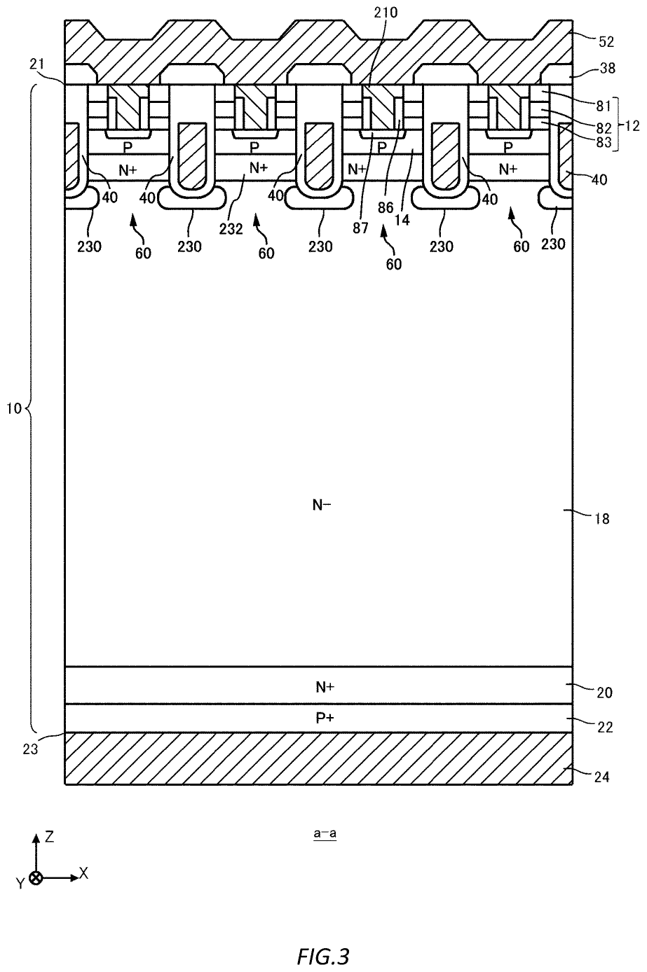

FIG. 3 is a view illustrating an example of a cross section taken along line a-a in FIG. 2. A cross section a-a is an XZ cross section passing through the emitter region 12 and the trench contact portion 210. In the cross section, the semiconductor device 100 of the present example includes the semiconductor substrate 10, an interlayer dielectric film 38, an emitter electrode 52, and a collector electrode 24.

The semiconductor substrate 10 has an upper surface 21 and a lower surface 23. The upper surface 21 and the lower surface 23 are two principal surfaces having a largest area among surfaces of the semiconductor substrate 10. A drift region 18 of the n type is provided inside the semiconductor substrate 10.

The emitter electrode 52 is provided above the upper surface 21 of the semiconductor substrate 10. A part of the upper surface 21 of the semiconductor substrate 10 is covered with the interlayer dielectric film 38. The emitter electrode 52 is in contact with at least a part of the upper surface 21 of the semiconductor substrate 10 that is not covered with the interlayer dielectric film 38. The emitter electrode 52 of the present example is in contact with the emitter region 12 and the trench contact portion 210.

The emitter electrode 52 is formed of a material including metal. For example, at least a partial region of the emitter electrode 52 is formed of aluminum or an aluminum-silicon alloy, for example, a metal alloy such as AlSi or AlSiCu. The emitter electrode 52 may have a barrier metal formed of titanium, titanium nitride, or the like below a region formed of aluminum or the like. The barrier metal may be in contact with the semiconductor substrate 10.

The interlayer dielectric film 38 is provided on the upper surface 21 of the semiconductor substrate 10. The interlayer dielectric film 38 is a film including at least one layer of a dielectric film such as silicate glass to which an impurity such as boron or phosphorous is added, a thermal oxide film, or other dielectric films. The interlayer dielectric film 38 may cover each trench portion. The interlayer dielectric film 38 may be provided inside the trench portion.

The collector electrode 24 is provided on the lower surface 23 of the semiconductor substrate 10. Similarly to the emitter electrode 52, the collector electrode 24 is formed of a metal material such as aluminum. In the present specification, a direction in which the emitter electrode 52 is connected to the collector electrode 24 (Z axis direction) is referred to as the depth direction.

A plurality of mesa portions 60 are provided on the upper surface 21 side of the semiconductor substrate 10. The emitter region 12, the trench contact portion 210, a contact dielectric film 86, a bottom region 87, and a base region 14 are provided in each mesa portion 60. Each configuration of the mesa portion 60 will be described below.

A plurality of gate trench portions 40 are provided at the upper surface 21 of the semiconductor substrate 10. Each gate trench portion 40 is provided from the upper surface 21 to the inside of the semiconductor substrate 10. The gate trench portion 40 of the present example penetrates the base region 14 from the upper surface 21 and reaches the drift region 18. A structure in which the trench portion penetrates the doping region is not limited to a structure which is made by forming the doping region and then forming the trench portion in order. A structure in which the trench portion is formed and then the doping region is formed between the trench portions is also included in the structure in which the trench portion penetrates the doping region.

The gate trench portion 40 includes a groove-shaped gate trench, a gate dielectric film 42, and a gate conductive portion 44 which are provided at the upper surface 21 of the semiconductor substrate 10. The gate conductive portion 44 is formed of polysilicon which is a conductive material. The gate dielectric film 42 is provided to cover an inner wall of the gate trench. The gate dielectric film 42 may be formed by oxidizing or nitriding a semiconductor on the inner wall of the gate trench. The gate conductive portion 44 is provided on an inner side further than the gate dielectric film 42 inside the gate trench. That is, the gate dielectric film 42 insulates the gate conductive portion 44 from the semiconductor substrate 10.

The gate conductive portion 44 in the gate trench portion 40 may be provided longer than the base region 14 in the depth direction. The gate trench portion 40 in the cross section is covered with the interlayer dielectric film 38 on the upper surface 21 of the semiconductor substrate 10. The gate conductive portion 44 is electrically connected to the gate wiring line 130 at a position other than the cross section illustrated in FIG. 3.

A lower end region 230 may or may not be provided in contact with a lower end of each gate trench portion 40. The lower end region 230 is a region of the p type. The lower end region 230 may be provided so as to cover a lowermost surface of the gate trench portion 40. The lower end region 230 is arranged separately from the base region 14. Providing the lower end region 230 can reduce electric field strength at the lower end of the gate trench portion 40. The lower end region 230 may be provided across a plurality of gate trench portions 40.

The semiconductor substrate 10 of the present example includes the drift region 18 of the N− type. The emitter region 12 has a higher doping concentration than the drift region 18. The drift region 18 is provided below the base region 14. The base region 14 is provided in contact with the gate trench portion 40. The drift region 18 may be in contact with the base region 14. In another example, an accumulation region 232 of the N+ type having a doping concentration higher than that of the drift region 18 may be provided between the drift region 18 and the base region 14, or may not be provided. Providing the accumulation region 232 can produce an electron injection enhancement effect to decrease an ON voltage of the semiconductor device 100.

A collector region 22 of the P+ type is provided between the drift region 18 and the lower surface 23 of the semiconductor substrate 10. A doping concentration of the collector region 22 is higher than a doping concentration of the base region 14. The collector region 22 may include an acceptor which is the same as or different from an acceptor of the base region 14. The acceptor of the collector region 22 is, for example, boron. The element serving as the acceptor is not limited to the example described above. The collector region 22 is exposed on the lower surface 23 of the semiconductor substrate 10 and is connected to the collector electrode 24. The collector electrode 24 may be in contact with the entire lower surface 23 of the semiconductor substrate 10. As described above, when a diode portion is provided in the active portion 160, the diode portion may be provided with a cathode region of the N+ type instead of the collector region 22.

A buffer region 20 of the N+ type may be provided between the drift region 18 and the collector region 22. A doping concentration of the buffer region 20 is higher than a doping concentration of the drift region 18. The buffer region 20 may have one or more concentration peaks with a doping concentration higher than that of the drift region 18. A doping concentration at a concentration peak refers to a doping concentration at a local maximum of the concentration peak. In addition, as the doping concentration of the drift region 18, an average value of doping concentrations in a region where a doping concentration distribution is substantially flat may be used.

The buffer region 20 may be formed by ion implantation of the dopant of the n type such as hydrogen (proton) or phosphorous. The buffer region 20 of the present example is formed by the ion implantation of hydrogen. The buffer region 20 may function as a field stopper layer which prevents a depletion layer expanding from a lower end of the base region 14 from reaching the collector region 22.

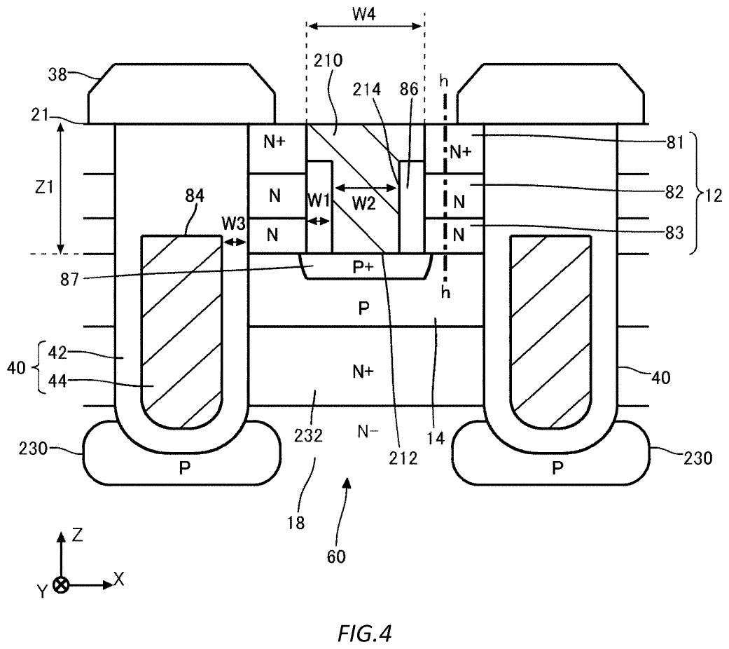

FIG. 4 is an enlarged view of a cross section in a vicinity of the mesa portion 60. As described above, the emitter region 12, the trench contact portion 210, the contact dielectric film 86, the bottom region 87, and the base region 14 are provided in the mesa portion 60. Below the base region 14 in the mesa portion 60, the drift region 18 of the N− type may be provided, and the accumulation region 232 of the n type having a concentration higher than that of the drift region 18 may be provided.

The trench contact portion 210 is provided from the upper surface 21 to the inside of the semiconductor substrate 10 in the mesa portion 60. The trench contact portion 210 of the present example is a plug formed of a conductive material such as tungsten. The trench contact portion 210 may be formed of a material different from that of the emitter electrode 52. A depth position (that is, a position in the Z axis direction) of a boundary between the trench contact portion 210 and the emitter electrode 52 may coincide with or may not coincide with the upper surface 21 of the semiconductor substrate 10.

The trench contact portion 210 has a bottom portion 212 and a side wall 214. The bottom portion 212 is a portion arranged at a lowermost part in the trench contact portion 210. The bottom portion 212 may be a plane parallel to the XY plane. In the trench contact portion 210, a portion within a predetermined distance in the depth direction from the portion arranged at the lowermost part may be defined as the bottom portion 212. The predetermined distance may be 0.1 μm, 0.2 μm, or 0.5 μm. The side wall 214 is a portion extending from the bottom portion 212 to the upper surface 21 of the semiconductor substrate 10 in the boundary of the trench contact portion 210 in the XZ cross section. The side wall 214 may extend in a direction parallel to the depth direction or may extend in a direction intersecting the depth direction in the XZ cross section. The side wall 214 may have a step shape in which an inclination changes discontinuously in the XZ cross section. In another example, in the side wall 214, the inclination may change continuously in the XZ cross section.

A region of the p type is provided below the trench contact portion 210. The trench contact portion 210 is in contact with the region of the p type. In the present example, the bottom region 87 is provided below the trench contact portion 210. The bottom region 87 is a region of the p type having a concentration higher than that of the base region 14. The bottom region 87 is in contact with the base region 14 and the conductive material of the trench contact portion 210. The base region 14 may be provided instead of the bottom region 87.

The emitter region 12 of the present example includes a first emitter portion 81 and a second emitter portion 82. The emitter region 12 may further include a third emitter portion 83. The first emitter portion 81 is a region of the n type which is provided between the side wall 214 of the trench contact portion 210 and the trench portion in the mesa portion 60. The first emitter portion 81 of the present example is a region of the N+ type having a concentration higher than that of the drift region 18. The first emitter portion 81 is connected to at least one of the emitter electrode 52 or the trench contact portion 210. In the example of FIG. 4, the first emitter portion 81 is connected to both the emitter electrode 52 and the trench contact portion 210. The first emitter portion 81 may be in contact with a side surface of the gate trench portion 40.

The second emitter portion 82 is provided below the first emitter portion 81 between the side wall 214 of the trench contact portion 210 and the trench portion. The second emitter portion 82 of the present example is a region of the N type having a doping concentration lower than that of the first emitter portion 81. The second emitter portion 82 is provided in contact with the first emitter portion 81. The second emitter portion 82 may be in contact with the side surface of the gate trench portion 40. The second emitter portion 82 of the present example is not in contact with the emitter electrode 52.

The contact dielectric film 86 is provided between the side wall 214 of the trench contact portion 210 and the second emitter portion 82. The contact dielectric film 86 may also be provided between the side wall 214 of the trench contact portion 210 and the third emitter portion 83 which will be described below. The contact dielectric film 86 of the present example is in contact with the side wall 214 of the trench contact portion 210. The contact dielectric film 86 may be a dielectric film formed by oxidizing or nitriding the semiconductor substrate 10 at a position in contact with the side wall 214, or may be a deposited film deposited at the position in contact with the side wall 214. The contact dielectric film 86 of the present example is a high-temperature oxide film (HTO) made of silicon or the like, but is not limited thereto.

The contact dielectric film 86 of the present example is provided so as to cover an entire side surface of the second emitter portion 82 facing the side wall 214 in the X axis direction. That is, the second emitter portion 82 is not in contact with the trench contact portion 210. Similarly, the contact dielectric film 86 is provided so as to cover an entire side surface of the third emitter portion 83 facing the side wall 214 in the X axis direction. That is, the third emitter portion 83 is not in contact with the trench contact portion 210.

The contact dielectric film 86 is not provided on at least a part of the bottom surface 212 of the trench contact portion 210. Accordingly, the trench contact portion 210 contacts a region of the p type such as the bottom region 87 or the base region 14.

The first emitter portion 81 includes a region that does not face the contact dielectric film 86 in the X axis direction. That is, the contact dielectric film 86 is not provided at at least a part of a side surface of the first emitter portion 81 facing the side wall 214 in the X axis direction. The contact dielectric film 86 may not be provided in an entire region between the side wall 214 and the first emitter portion 81. The first emitter portion 81 of the present example is in contact with the side wall 214 of the trench contact portion 210. The entire side surface of the first emitter portion 81 may be in contact with the side wall 214.

By providing the contact dielectric film 86, a total current flowing between the second emitter portion 82 and the emitter electrode 52 passes through the first emitter portion 81. In addition, a total current flowing between the first emitter portion 81 and the base region 14 passes through the second emitter portion 82.

The second emitter portion 82 of the present example has a doping concentration lower than that of the first emitter portion 81. This increases a resistance value of the second emitter portion 82. In addition, a current flowing between the first emitter portion 81 and the base region 14 passes through the second emitter portion 82. Therefore, by providing the second emitter portion 82, a resistance of the emitter region 12 can be increased.

By increasing the resistance of the emitter region 12, it is possible to achieve both a relatively low saturation current and a relatively low ON voltage. A MOS structure provided at the upper surface 21 of the semiconductor substrate 10 has a saturation characteristic in which a collector current is saturated even when a voltage between a collector and an emitter is increased. Accordingly, the semiconductor device 100 has a short-circuit withstand characteristic in which an element is not destroyed within a certain period of time in a short-circuit state in which a high current and a high voltage are simultaneously applied. When the MOS structure is formed in all the mesa portions 60 in a state where device miniaturization has progressed, a saturation current becomes extremely high, and thus, there is a case where the saturation current is suppressed by a thinned structure in which the MOS structure is not formed in some mesa portions 60, a ladder structure in which the emitter regions 12 elongated in the X axis direction are discretely arranged in the Y axis direction, or the like. However, when the saturation current is suppressed with such a structure, the ON voltage becomes high.

A current saturation characteristic of the MOS structure is expressed by following Expression 1.

$$Isat = \frac{Z μ nCox}{Lch} [ \frac{1}{2} {( Vge - Vth )}^{2} ] \qquad Expression 1$$

Isat represents a saturation current, Z represents a total emitter width of the emitter region 12 (that is, a total length in the Y axis direction), un represents electron mobility, Cox represents a capacitance of the gate dielectric film 42, Lch represents a channel length in the Z axis direction, Vge represents a gate-emitter voltage, and Vth represents a threshold voltage.

A channel resistance Rch of the MOS structure is expressed by following Expression 2.

$$Rch \approx \frac{Lch}{Z μ nCox ( Vge - Vth )} \qquad Expression 2$$

Comparison between Expressions 1 and 2 shows that decreasing the saturation current Isat increases the channel resistance Rch, and increasing the saturation current Isat decreases the channel resistance Rch. That is, when the saturation current is decreased to improve short-circuit withstand capability of the semiconductor device 100, the ON voltage is increased, which is a trade-off correlation. For example, in the thinned emitter structure, the emitter region 12 is formed in some of the mesa portions 60, and thus supply of an electron current to the drift region 18 becomes sparse in the X axis direction, causing an uneven current flow and an increase in the ON voltage. In addition, in the ladder structure in which the emitter regions 12 elongated in the X axis direction are discretely arranged in the Y axis direction, it is difficult to increase a length Z (corresponding to a channel width) along which the gate trench portion 40 and the emitter region 12 are in contact with each other.

In this regard, in the semiconductor device 100, the second emitter portion 82 is provided to suppress the saturation current. When the semiconductor device 100 is turned on, a current flows between the emitter electrode 52 and the emitter region 12 via the second emitter portion 82. Therefore, a potential of the emitter region 12 changes according to a magnitude of a current flowing through the second emitter portion 82. Since a current flows from the emitter region 12 to the emitter electrode 52, when the current flowing through the second emitter portion 82 is larger, the potential of the emitter region 12 becomes higher. When the current flowing through the second emitter portion 82 is small, the potential of the emitter region 12 increases only slightly.

Since the ON voltage applied to the gate conductive portion 44 is substantially a constant voltage, when the current flowing through the second emitter portion 82 increases, a potential difference between the gate conductive portion 44 and the emitter region 12 decreases, and a voltage applied to the gate dielectric film 42 decreases. On the other hand, when the current flowing through the second emitter portion 82 is small, the voltage applied to the gate dielectric film 42 becomes relatively large. Therefore, a saturation current flowing through the MOS structure can be suppressed.

In the semiconductor device 100, by providing the emitter region 12 elongated in the Y axis direction, the total emitter width Z can be increased and the ON voltage can be reduced. Accordingly, it is possible to achieve both a low saturation current and a low ON voltage.

A lower end of the trench contact portion 210 is in contact with the bottom region 87 of the p type. The bottom region 87 can be formed by forming a trench for forming the trench contact portion 210 and then implanting dopant ions of the p type into the trench from above. The bottom region 87 may be a region of the P+ type having a concentration higher than that of the base region 14. A doping concentration of the bottom region 87 may be 2 times or more, 5 times or more, 10 times or more, 50 times or more, or 100 times or more the doping concentration of the base region 14.

The trench contact portion 210 is provided from the upper surface 21 of the semiconductor substrate 10 to a position deeper than the lower end of the second emitter portion 82. The bottom region 87 is in contact with the base region 14. Providing the high-concentration bottom region 87 can reduce a contact resistance between the trench contact portion 210 and the base region 14.

The third emitter portion 83 is provided below the second emitter portion 82 between the side wall 214 of the trench contact portion 210 and the trench portion. The third emitter portion 83 is a region of the N type having a doping concentration higher than that of the second emitter portion 82. The third emitter portion 83 is provided in contact with the second emitter portion 82. The third emitter portion 83 may have a doping concentration lower than that of the first emitter portion 81. The third emitter portion 83 may be in contact with a side surface of the trench portion. The third emitter portion 83 of the present example is not in contact with the emitter electrode 52.

By providing the third emitter portion 83, the second emitter portion 82 can be prevented from being in direct contact with the base region 14. Therefore, a dopant of the base region 14 can be suppressed from diffusing into the second emitter portion 82 having a low concentration, and a length of the second emitter portion 82 in the depth direction can be accurately controlled. Therefore, it is possible to suppress a variation in the resistance value in the second emitter portion 82.

The contact dielectric film 86 of the present example is also provided between the side wall 214 of the trench contact portion 210 and the third emitter portion 83. Accordingly, the third emitter portion 83 is not in contact with the trench contact portion 210.

An upper end 84 of the gate conductive portion 44 of the gate trench portion 40 is preferably arranged to face the third emitter portion 83 in the X axis direction. The upper end 84 of the gate conductive portion 44 may refer to an upper end of a side wall of the gate conductive portion 44. The upper end 84 and the third emitter portion 83 facing each other means that the upper end 84 is arranged between an upper end position and a lower end position of the third emitter portion 83 in the Z axis direction. The upper end and the lower end of the third emitter portion 83 may refer to an upper end and a lower end of its portion in contact with a side wall of the gate trench portion 40.

When the ON voltage is applied to the gate conductive portion 44, electrons are attracted to a region of the mesa portion 60 that faces the gate conductive portion 44, in a boundary portion between the mesa portion 60 and the trench portion. When the second emitter portion 82 and the gate conductive portion 44 are arranged to face each other, electrons are also attracted to a boundary portion of the second emitter portion 82. Since the second emitter portion 82 has a low doping concentration, a resistance value at the boundary portion may fluctuate due to the attracted electrons. In this regard, the third emitter portion 83 is arranged to face the upper end 84 of the gate conductive portion 44, whereby it is possible to suppress the fluctuation in the resistance value at the boundary portion of the second emitter portion 82. In addition, since the third emitter portion 83 has a high doping concentration, even if electrons are attracted to a boundary portion of the third emitter portion 83, the fluctuation in the resistance value of the boundary portion is extremely small.

Each mesa portion 60 is provided with the base region 14 of the P− type. The base region 14 is in contact with the gate trench portion 40. The base region 14 may be in contact with each of trench portions on both sides of the mesa portion 60. At least a portion of the base region 14 is provided below the emitter region 12. The base region 14 may be in contact with the emitter region 12. When a predetermined ON voltage is applied to the gate trench portion 40, a surface layer of the base region 14 in contact with the gate trench portion 40 is inverted to a region of the n type to form a channel. The emitter region 12 is electrically connected by the channel to a drift region 18 which will be described below.

The base region 14 is also provided below the trench contact portion 210. The base region 14 may be in contact with the trench contact portion 210 or may be in contact with the bottom region 87. A doping concentration of the base region 14 may be 5.0×10¹⁶ atoms/cm³ or more and 1.0×10¹⁸ atoms/cm³ or less.

According to the present example, a resistance value in the emitter region 12 can be accurately controlled by providing the contact dielectric film 86 on the side wall 214 of the trench contact portion 210. For example, even when a region of the p type is provided instead of the contact dielectric film 86, the resistance value in the emitter region 12 can be controlled by limiting a current path in the emitter region 12. However, the resistance value in the emitter region 12 also varies depending on a variation in a doping concentration or the like of the region of the p type. In the present example, the current path in the emitter region 12 can be accurately limited by providing the contact dielectric film 86.

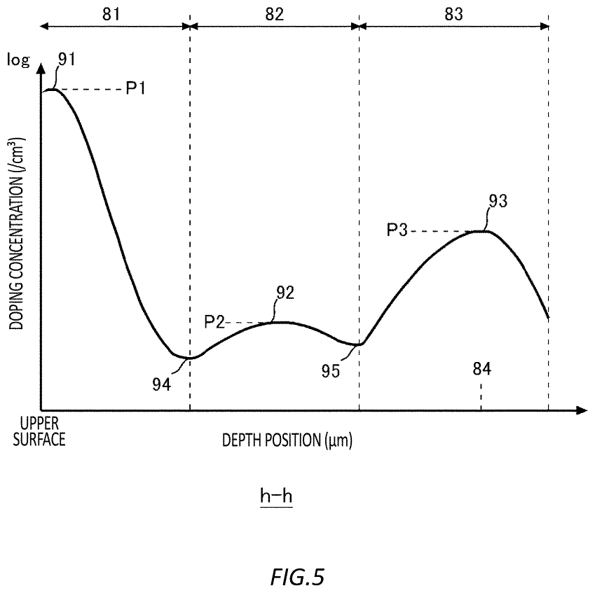

FIG. 5 is a view illustrating an example of a doping concentration distribution taken along line h-h in FIG. 4. Line h-h is a line that passes through the first emitter portion 81, the second emitter portion 82, and the third emitter portion 83 and is parallel to the Z axis.

The first emitter portion 81 of the present example has a peak 91 of the doping concentration distribution in the depth direction. The peak of the doping concentration distribution is a mountain-shaped portion showing a local maximum value at a local maximum. A doping concentration at the local maximum of the peak is defined as a doping concentration of the peak. The doping concentration of the peak 91 is defined as P1. Note that the doping concentration of the first emitter portion 81 may continuously increase from the boundary with the second emitter portion 82 to the upper surface 21 of the semiconductor substrate 10. In this case, the doping concentration of the first emitter portion 81 at the upper surface 21 is defined as P1.

The second emitter portion 82 of the present example has a peak 92 of the doping concentration distribution in the depth direction. The doping concentration of the peak 92 is defined as P2. Between the first emitter portion 81 and the second emitter portion 82, a valley portion 94 in which the doping concentration shows a local minimum value is defined as a boundary between the first emitter portion 81 and the second emitter portion 82.

The third emitter portion 83 of the present example has a peak 93 of the doping concentration distribution in the depth direction. The doping concentration of the peak 93 is defined as P3. Between the second emitter portion 82 and the third emitter portion 83, a valley portion 95 in which the doping concentration shows a local minimum value is defined as a boundary between the second emitter portion 82 and the third emitter portion 83.

As described above, the concentration P2 of the peak 92 of the second emitter portion 82 is lower than the concentration P1 of the peak 91 of the first emitter portion 81. The concentration P2 may be 1/100 times or less, or 1/1000 times or less the concentration P1. The concentration P2 may be 10 times or less or 5 times or less the doping concentration of the valley portion 94. The concentration P2 is higher than the doping concentration of the drift region 18. The concentration P2 may be 100 times or less, 10 times or less, or 5 times or less the doping concentration of the drift region 18. A resistance value in the emitter region 12 can be adjusted by adjusting the concentration P2.

The length of the second emitter portion 82 in the depth direction may be 2 μm or less. The length may be 1.5 μm or less or 1 μm or less. The length may be 0.1 μm or more, or 0.5 μm or more. A length of the entire emitter region 12 in the depth direction may be 3 μm or less.

The emitter region 12 of the present example can be formed by implanting dopant ions of the n type into each position of the peak 91, the peak 92, and the peak 93. The length of the second emitter portion 82 can be adjusted by depth positions forming the peak 91 and the peak 93. The resistance value in the emitter region 12 can be adjusted by adjusting the length of the second emitter portion 82.

As described above, the concentration P3 of the peak 93 of the third emitter portion 83 is higher than the concentration P2 of the peak 92 of the second emitter portion 82. The concentration P3 may be 10 times or more, 50 times or more, or 100 times or more the concentration P2. The concentration P3 of the peak 93 of the third emitter portion 83 may be less than or equal to the concentration P1 of the peak 91 of the first emitter portion 81. The concentration P3 may be ½ times or less, ⅕ times or less, or 1/10 times or less the concentration P1.

As described in FIG. 4, a depth position of the upper end 84 of the gate conductive portion 44 is included in a depth range in which the third emitter portion 83 is provided. The upper end 84 may be provided within a range of a full width at half maximum of the peak 93. A range of the full width at half maximum of the peak 93 is a range in which the doping concentration is half or more of P3 at the peak 93.

A length of the third emitter portion 83 in the depth direction may be 0.4 μm or more. Accordingly, even when the depth position of the upper end 84 of the gate conductive portion 44 fluctuates due to a manufacturing variation or the like, the upper end 84 can be arranged at a position facing the third emitter portion 83. The length of the third emitter portion 83 in the depth direction may be 1 μm or less. The third emitter portion 83 is only required to be able to absorb a variation in the depth position of the upper end 84. A total length of the emitter region 12 can be reduced by setting the length of the third emitter portion 83 to 1 μm or less.

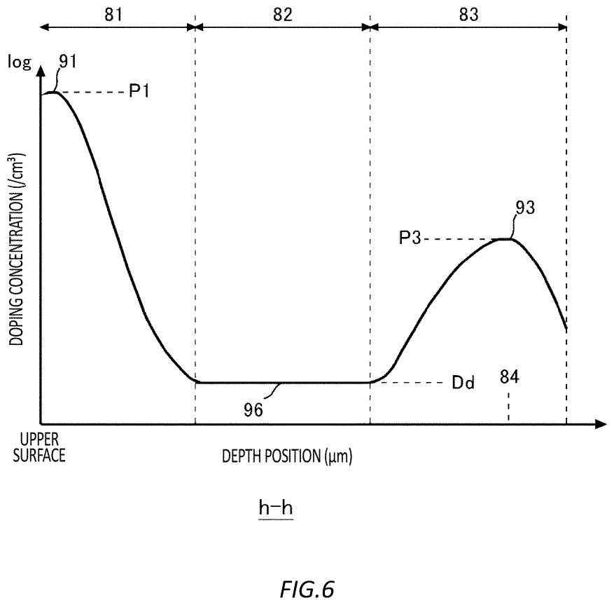

FIG. 6 is a view illustrating another example of the doping concentration distribution taken along line h-h. In the doping concentration distribution of the present example, a distribution in the second emitter portion 82 is different from that of the example of FIG. 6. Distributions in the first emitter portion 81 and the third emitter portion 83 are similar to those in the example of FIG. 5.

The second emitter portion 82 of the present example has a flat portion 96 having a flat doping concentration distribution in the depth direction. For example, the flat portion 96 is a portion in which a maximum value of the doping concentration is 2 times or less a minimum value of the doping concentration. A length of the flat portion 96 in the depth direction may be 0.1 μm or more, or 0.5 μm or more.

The minimum value of the doping concentration of the flat portion 96 may be 10 times or less, 5 times or less, or 2 times or less a doping concentration Dd. The minimum value of the doping concentration of the flat portion 96 may be the same as the doping concentration Dd of the drift region 18. In the present example, dopant ions of the n type are not implanted into the second emitter portion 82.

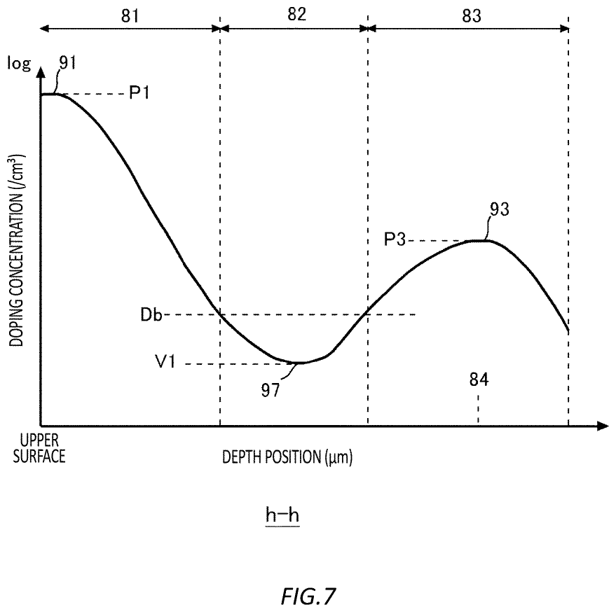

FIG. 7 is a view illustrating another example of the doping concentration distribution taken along line h-h. In the doping concentration distribution of the present example, the distribution in the second emitter portion 82 is different from that of the example of FIG. 5. The distributions in the first emitter portion 81 and the third emitter portion 83 are similar to those in the example of FIG. 5.

The second emitter portion 82 of the present example has a valley portion 97 in which the doping concentration exhibits a local minimum value in the depth direction. The local minimum value of the doping concentration in the valley portion 97 is defined as V1. The concentration V1 may be 100 times or less, 50 times or less, 10 times or less, or 5 times or less the doping concentration Dd of the drift region 18. The concentration V1 may be the same as the concentration Dd. In the present example, dopant ions of the n type are not implanted into the second emitter portion 82. The valley portion 97 in a vicinity of a boundary between the first peak 91 and the third peak 93 functions as the second emitter portion 82.

A doping concentration at both ends of the second emitter portion 82 in the depth direction is defined as Db. The concentration Db may be 10 times, 5 times, or another value of the concentration V1. The length of the second emitter portion 82 in the depth direction is similar to that in the example of FIG. 5 or 6.

The second emitter portion 82 has any one of the peak 92 shown in FIG. 5, the flat portion 96 shown in FIG. 6, or the valley portion 97 shown in FIG. 7. The second emitter portion 82 may be provided with two or more of the peak 92, the flat portion 96, or the valley portion 97.

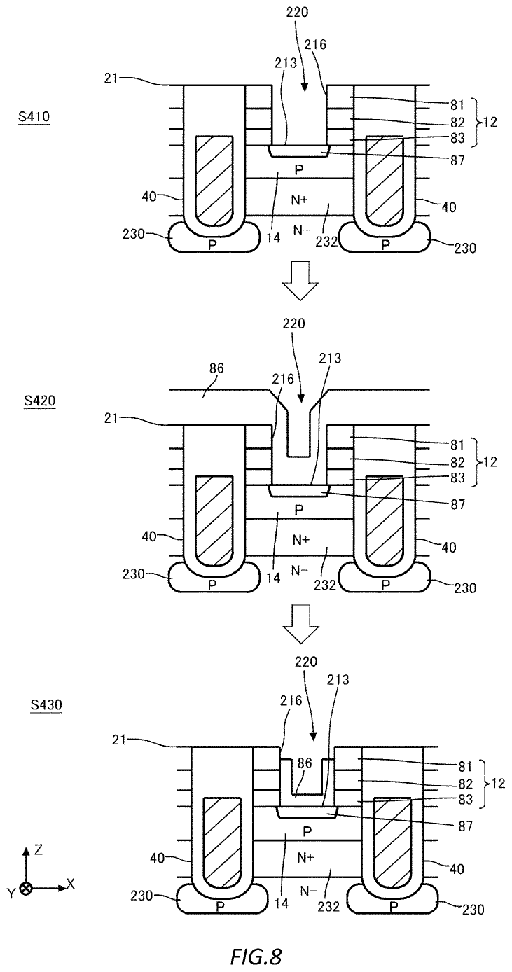

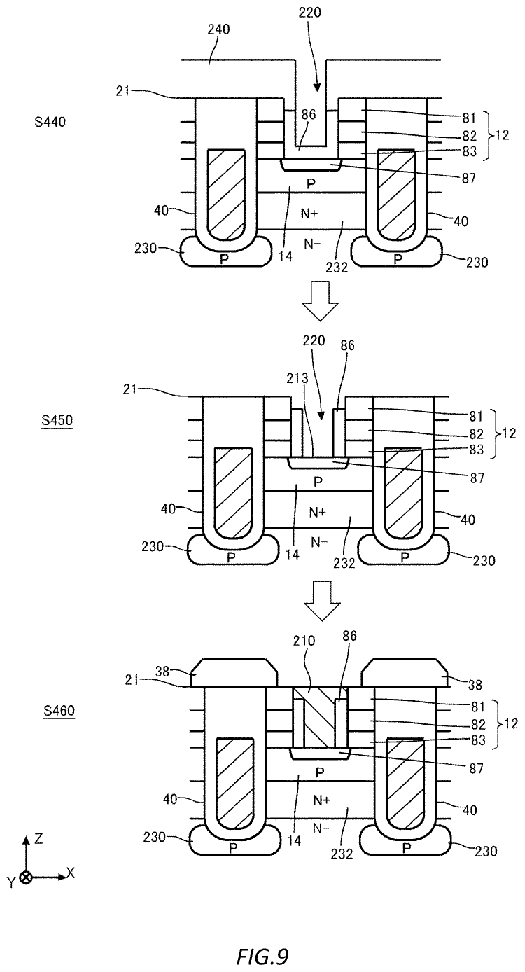

FIGS. 8 and 9 each are a view illustrating a partial process of a manufacturing process of the semiconductor device 100. FIGS. 8 and 9 each illustrate a process of forming the trench contact portion 210, the contact dielectric film 86, and the bottom region 87.

In step S410 of the present example, the gate trench portion 40, the mesa portion 60, the bottom region 87, the accumulation region 232, the lower end region 230, the emitter region 12, and the base region 14 are formed in the semiconductor substrate 10. In addition, in S410, a contact trench 220 for forming the trench contact portion 210 is formed in the mesa portion 60. In S410, the contact trench 220 may be formed by anisotropic etching, or the contact trench 220 may be formed by isotropic etching. Before the contact trench 220 is formed, each portion of the emitter region 12 may be provided in the entire mesa portion 60 in the X axis direction. In another example, each portion of the emitter region 12 may be formed after the contact trench 220 is formed.

The contact trench 220 has a side wall 216 and a bottom surface 213. The bottom surface 213 is a surface including a lower end of the contact trench 220. The bottom surface 213 may be a surface parallel to the XY plane. In another example, the bottom surface 213 may be a portion of a surface of the contact trench 220, a distance from which to the lower end of the contact trench 220 in the Z axis direction is within a predetermined value. The predetermined value may be, for example, 0.1 μm, 0.2 μm, or 0.5μ m.

The side wall 216 is a portion of the surface of the contact trench 220 which extends from the bottom surface 213 to the upper surface 21 of the semiconductor substrate 10. At least a portion of the side wall 216 may be provided parallel to the Z axis direction, or may be provided at an angle.

Each portion of the emitter region 12 is exposed on the side wall 216. The first emitter portion 81, the second emitter portion 82, and the third emitter portion 83 are exposed on the side wall 216 of FIG. 8.

The bottom region 87 is exposed on the bottom surface 213 of the present example. The bottom region 87 may be exposed over the entire bottom surface 213. After the contact trench 220 is formed and before the contact dielectric film 86 is formed, a dopant of the p type may be implanted into the bottom surface 213 of the contact trench 220 to form the bottom region 87. When the bottom region 87 is not provided, the base region 14 may be exposed on the bottom surface 213.

In step S420, the contact dielectric film 86 is formed on the side wall 216 and the bottom surface 213 of the contact trench 220. The contact dielectric film 86 may cover the entire side wall 216 and the entire bottom surface 213. In S420, the contact dielectric film 86 may also be formed on the upper surface 21 of the semiconductor substrate 10. The contact dielectric film 86 may be formed by a CVD method or may be formed by another method.

In step S420, the contact dielectric film 86 may be formed such that a portion of the contact trench 220 is not filled with the contact dielectric film 86. As illustrated in FIG. 8, a recess reaching an inside of the contact trench 220 may be provided on an upper surface of the contact dielectric film 86 formed in S420. The recess can be formed by adjusting a thickness of the contact dielectric film 86.

In step S430, a part of the contact dielectric film 86 is etched to expose the first emitter portion 81 on the side wall 216 of the contact trench 220. After the etching, a part of the side surface of the first emitter portion 81 may be covered with the contact dielectric film 86, and the entire side surface of the first emitter portion 81 may be exposed on the side wall 216. After the contact dielectric film 86 is etched in S430, the contact dielectric film 86 covers the entire side surface of the second emitter portion 82. In the present example, after the contact dielectric film 86 is etched, the contact dielectric film 86 also covers the entire side surface of the third emitter portion 83. In S430, the contact dielectric film 86 may be etched such that the bottom surface 213 of the contact trench 220 is not exposed. In another example, after the etching in S430, at least a part of the bottom surface 213 may be exposed without being covered with the contact dielectric film 86. In this example, step S440 and step S450 which will be described below may not be performed.

In S430, the contact dielectric film 86 on the upper surface 21 of the semiconductor substrate 10 is etched by anisotropic etching. That is, in S430, the entire contact dielectric film 86 is etched from the upper surface 21 side of the semiconductor substrate 10. Since the thickness in the Z axis direction of the contact dielectric film 86 covering the side wall 216 is large, the contact dielectric film 86 remains on the side wall 216 even if the entire contact dielectric film 86 is etched by anisotropic etching. In S430, etching conditions such as etching time are adjusted such that the second emitter portion 82 is not exposed.

In step S440 in FIG. 9, a mask 240 which covers the upper surface 21 of the semiconductor substrate 10 and the contact dielectric film 86 provided on the side wall of the contact trench 220 is formed. The mask 240 is, for example, a photosensitive resist. The mask 240 may cover at least an upper end of the contact dielectric film 86 provided on the side wall 216. The mask 240 does not cover at least a part of the contact dielectric film 86 provided on the bottom surface 213.

In step S450, after the mask 240 is formed, the contact dielectric film 86 provided on the bottom surface 213 of the contact trench 220 is etched. The contact dielectric film 86 on the bottom surface 213 may be etched by anisotropic etching. By the etching processing from S430 to S450, it is possible to expose a region of the p type (the bottom region 87 or the base region 14) on the bottom surface 213 while leaving the contact dielectric film 86 covering the second emitter portion 82 and the third emitter portion 83 at the side wall 216. In S450, the mask 240 is removed after the contact dielectric film 86 on the bottom surface 213 is etched.

In step S460, the inside of the contact trench 220 is filled with a conductive material, and the conductive material is brought into contact with the first emitter portion 81 and the region of the p type (the bottom region 87 or the base region 14). Accordingly, the trench contact portion 210 can be formed which is in contact with the first emitter portion 81 and the region of the p type and is insulated from the second emitter portion 82 and the third emitter portion 83 by the contact dielectric film 86. As described above, the conductive material is tungsten, for example. The conductive material may be formed by a sputtering method or the like.

As illustrated in FIG. 4, the thickness in the X axis direction of the contact dielectric film 86 remaining inside the contact trench 220 after the contact trench 220 is filled with the conductive material in S460 is defined as W1, and the thickness in the X axis direction of the conductive material is defined as W2. As the thickness W1, a maximum value of the thickness of the contact dielectric film 86 may be used, or a thickness at a center in the Z axis direction of the contact dielectric film 86 may be used. As the thickness W2, a maximum value of the thickness of the conductive material sandwiched between the contact dielectric films 86 may be used, or a thickness at a center in the Z axis direction of the conductive material sandwiched between the contact dielectric films 86 may be used. In addition, a thickness in the X axis direction of an in-trench dielectric film, which covers an inner wall of the trench portion, in the trench portion is defined as W3. In the present example, the gate dielectric film 42 of the gate trench portion 40 corresponds to the in-trench dielectric film. As the thickness W3, a maximum value of the thickness of the gate dielectric film 42 sandwiched between the gate conductive portion 44 and the semiconductor substrate 10 may be used, or a thickness at a center in the Z axis direction of the gate dielectric film 42 sandwiched between the gate conductive portion 44 and the semiconductor substrate 10 may be used. An opening width in the X axis direction of the trench contact portion 210 (that is, an opening width of the contact trench 220 formed in S410) at the upper surface 21 of the semiconductor substrate 10 is defined as W4. As the opening width W4, a maximum value of the opening width in the X axis direction of the trench contact portion 210 (or the contact trench 220) may be used. In addition, a depth of the trench contact portion 210 is defined as Z1. The depth Z1 is a distance in the Z axis direction from the upper surface 21 of the semiconductor substrate 10 to a lowermost end of the trench contact portion 210.

The thickness W1 of the contact dielectric film 86 may be smaller than the depth Z1 of the trench contact portion 210. If the thickness W1 is excessively large, it is difficult to form a recess on the upper surface of the contact dielectric film 86 as illustrated in S420 of FIG. 8. Therefore, in the etching in S430, it becomes difficult to leave the contact dielectric film 86 on the side wall 216 of the contact trench 220. The thickness W1 may be less than or equal to half, or ¼, of the depth Z1.

The thickness W2 of the conductive material may be larger than the thickness W1 of the contact dielectric film 86. The thickness W2 of the conductive material may be more than or equal to 2 times, or 4 times, the thickness W1 of the contact dielectric film 86.

The thickness W1 of the contact dielectric film 86 may be smaller than the thickness W3 of the in-trench dielectric film (for example, the gate dielectric film 42). The thickness W1 may be less than or equal to 0.8 times, or 0.5 times, the thickness W3. The contact dielectric film 86 and the in-trench dielectric film may be dielectric films formed of different materials or formed by different methods. As an example, the contact dielectric film 86 may be a high-temperature oxide film (HTO) formed by a CVD method, and the in-trench dielectric film may be a thermal oxide film obtained by thermally oxidizing the semiconductor substrate 10. The contact dielectric film 86 and the interlayer dielectric film 38 may be dielectric films formed of different materials or formed by different methods. As an example, the interlayer dielectric film 38 is a BPSG film or a BSG film. The thickness W1 of the contact dielectric film 86 may be smaller than a maximum value of a thickness in the Z axis direction of the interlayer dielectric film 38.

The opening width W4 of the contact trench 220 may be 0.8 μm or more and 2 μm or less. The opening width W4 may be 1 μm or more, or may be 1.2 μm or more. The opening width W4 may be 1.8 μm or less, or may be 1.6 μm or less.

The thickness W1 of the contact dielectric film 86 after the etching in S450 may be 0.3 μm or more and 0.7 μm or less. The thickness W1 may be 0.35 μm or more, or may be 0.4 μm or more. The thickness W1 may be 0.65 μm or less, or may be 0.6 μm or less.

The depth Z1 of the trench contact portion 210 may be 0.8 μm or more and 2 μm or less. The depth Z1 may be 1 μm or more, or may be 1.2 μm or more. The depth Z1 may be 1.8 μm or less, or may be 1.6 μm or less.

A thickness in the Z axis direction of the first emitter portion 81 at a position in contact with the gate trench portion 40 may be 0.05 μm or more and 1 μm or less. The thickness may be 0.1 μm or more. The thickness may be 0.5 μm or less.

A thickness in the Z axis direction of the second emitter portion 82 at a position in contact with the gate trench portion 40 may be 0.05 μm or more and 1 μm or less. The thickness may be 0.1 μm or more. The thickness may be 0.5 μm or less.

A thickness in the Z axis direction of the third emitter portion 83 at a position in contact with the gate trench portion 40 may be 0.2 μm or more and 2 μm or less. The thickness may be 0.5 μm or more. The thickness may be 1.5 μm or less.

In the example illustrated in FIGS. 8 and 9, the bottom region 87 is formed in S420. In another example, after the contact dielectric film 86 on the bottom surface 213 is etched in S450 and before the contact trench 220 is filled with the conductive material in S460, a dopant of the p type may be implanted into the bottom surface 213 of the contact trench 220 to form the bottom region 87. In this case, the bottom region 87 can be prevented from being etched in the etching processing of the contact dielectric film 86 on the bottom surface 213. Therefore, the bottom region 87 can be formed accurately.

An angle formed between the side wall 216 of the contact trench 200 formed in S410 and the Z axis direction may be less than 5 degrees. The angle may be less than 3 degrees. As the angle of the side wall 216, a value at a center in the Z axis direction of the side wall 216 may be used. By reducing the angle formed between the side wall 216 and the Z axis direction, when the contact dielectric film 86 is etched in S430, it becomes easy to remove the contact dielectric film 86 on an upper side of the side wall 216 and leave the contact dielectric film 86 on a lower side thereof.

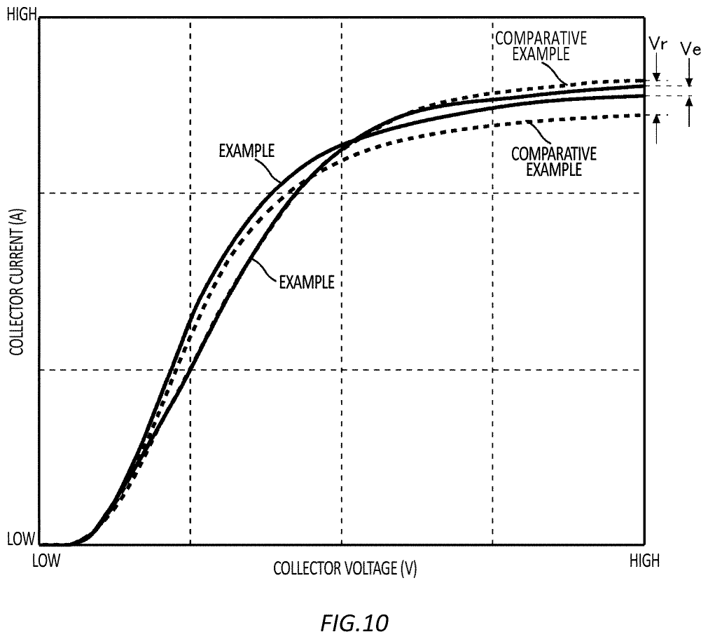

FIG. 10 is a view illustrating an example of collector voltage-collector current characteristics of the semiconductor device 100. FIG. 10 illustrates a plurality of characteristics according to an example in which the contact dielectric film 86 described in FIGS. 1 to 9 is provided and a plurality of characteristics according to a comparative example in which a region of the p type is provided instead of the contact dielectric film 86. In the comparative example, the side wall of the contact trench 220 was formed in parallel with the depth direction, and dopant ions of the p type were implanted in parallel with the depth direction to form the region of the p type.

In FIG. 10, the characteristics of the comparative example are indicated by broken lines, and the characteristics of the example are indicated by solid lines. As illustrated in FIG. 10, in the comparative example, a variation Vr in the saturation current of the collector current is large. On the other hand, in the example, a variation Ve in the saturation current of the collector current is small. In the example, it is considered that the current path in the emitter region 12 can be limited accurately, and the variation Ve in the saturation current is reduced.

While the present invention has been described above by way of the embodiments, the technical scope of the present invention is not limited to the scope described in the above-described embodiments. It is apparent to persons skilled in the art that various alterations or improvements can be made to the above-described embodiments. It is also apparent from the description of the claims that the embodiments to which such alterations or improvements are made can fall within the technical scope of the present invention.

Each process of the operations, procedures, steps, stages, and the like performed by a device, system, program, and method shown in the claims, the specification, and the drawings can be performed in any order as long as the order is not indicated by “prior to,” “before,” and the like and as long as the output from a previous process is not used in a later process. Even if the operational flow is described using phrases such as “first” or “next” for convenience in the claims, the specification, and the drawings, it does not necessarily mean that the process must be performed in this order.

What is claimed is:

1. A manufacturing method of a semiconductor device which is provided in a semiconductor substrate having an upper surface and a lower surface and including a drift region of a first conductivity type, wherein
the semiconductor device includes a plurality of trench portions which are provided from the upper surface to an inside of the semiconductor substrate, a mesa portion which is sandwiched between two of the trench portions in the semiconductor substrate, a trench contact portion which is provided from the upper surface to an inside of the semiconductor substrate in the mesa portion, a first emitter portion of the first conductivity type which is provided between a side wall of the trench contact portion and the trench portion in the mesa portion, a second emitter portion of the first conductivity type which is provided below the first emitter portion between the side wall of the trench contact portion and the trench portion and has a doping concentration lower than that of the first emitter portion, a region of a second conductivity type which is provided below the trench contact portion, and a contact dielectric film which is provided between the side wall of the trench contact portion and the second emitter portion,
the manufacturing method comprises:
forming a contact trench for forming the trench contact portion in the mesa portion;
forming the contact dielectric film on a side wall and a bottom surface of the contact trench;
etching a part of the contact dielectric film to expose the first emitter portion on the side wall of the contact trench and to expose the region of the second conductivity type on the bottom surface of the contact trench; and
filling an inside of the contact trench with a conductive material to bring the conductive material into contact with the first emitter portion and the region of the second conductivity type.

2. The manufacturing method according to claim 1, wherein
the contact dielectric film is also formed on the upper surface of the semiconductor substrate,
the manufacturing method comprises:
etching the contact dielectric film on the upper surface of the semiconductor substrate by anisotropic etching;
forming a mask which covers the upper surface of the semiconductor substrate and the contact dielectric film provided on the side wall of the contact trench; and
etching the contact dielectric film provided on the bottom surface of the contact trench.

3. The manufacturing method according to claim 1, wherein
the contact dielectric film covers an entire side surface of the second emitter portion after the contact dielectric film is etched.

4. The manufacturing method according to claim 3, wherein
the semiconductor device further includes a third emitter portion of the first conductivity type which is provided below the second emitter portion between the side wall of the trench contact portion and the trench portion and has a doping concentration higher than that of the second emitter portion, and
the contact dielectric film covers an entire side surface of the third emitter portion after the contact dielectric film is etched.

5. The manufacturing method according to claim 1, wherein
a thickness of the contact dielectric film is smaller than a depth of the trench contact portion.

6. The manufacturing method according to claim 1, wherein
after the contact trench is filled with the conductive material, among the conductive material and the contact dielectric film remaining inside the contact trench, the conductive material has a relatively large thickness in a first direction parallel to the upper surface of the semiconductor substrate.

7. The manufacturing method according to claim 6, wherein
a thickness of the conductive material is 2 times or more a thickness of the contact dielectric film.

8. The manufacturing method according to claim 1, wherein
the trench portion includes an in-trench dielectric film which covers an inner wall of the trench portion, and
the contact dielectric film is thinner than the in-trench dielectric film.

9. The manufacturing method according to claim 1, wherein
the semiconductor device further includes a base region of the second conductivity type which is provided in contact with the trench portion,
the region of the second conductivity type is in contact with the base region and the conductive material and has a concentration higher than that of the base region, and
in the manufacturing method,
after the contact trench is formed and before the contact dielectric film is formed, a dopant of the second conductivity type is implanted into the bottom surface of the contact trench to form the region of the second conductivity type.

10. The manufacturing method according to claim 1, wherein
the semiconductor device further includes a base region of the second conductivity type which is provided in contact with the trench portion,
the region of the second conductivity type is in contact with the base region and the conductive material and has a concentration higher than that of the base region, and
in the manufacturing method,
after the contact dielectric film is etched and before the contact trench is filled with the conductive material, a dopant of the second conductivity type is implanted into the bottom surface of the contact trench to form the region of the second conductivity type.

11. The manufacturing method according to claim 1, wherein
an opening width of the contact trench at the upper surface of the semiconductor substrate is 0.8 μm or more and 2 μm or less, and
a thickness of the contact dielectric film after the contact dielectric film is etched is 0.3 μm or more and 0.7 μm or less.

12. The manufacturing method according to claim 1, wherein
the semiconductor substrate is a wide band gap substrate formed of a material having a band gap larger than that of silicon.

13. The manufacturing method according to claim 1, wherein
an angle formed between a side wall of the contact trench and a depth direction is less than 5 degrees.

14. The manufacturing method according to claim 2, wherein
a thickness of the contact dielectric film is smaller than a depth of the trench contact portion.

15. The manufacturing method according to claim 3, wherein
a thickness of the contact dielectric film is smaller than a depth of the trench contact portion.

16. The manufacturing method according to claim 4, wherein
a thickness of the contact dielectric film is smaller than a depth of the trench contact portion.

17. The manufacturing method according to claim 2, wherein
after the contact trench is filled with the conductive material, among the conductive material and the contact dielectric film remaining inside the contact trench, the conductive material has a relatively large thickness in a first direction parallel to the upper surface of the semiconductor substrate.

18. The manufacturing method according to claim 3, wherein
after the contact trench is filled with the conductive material, among the conductive material and the contact dielectric film remaining inside the contact trench, the conductive material has a relatively large thickness in a first direction parallel to the upper surface of the semiconductor substrate.

19. The manufacturing method according to claim 4, wherein
after the contact trench is filled with the conductive material, among the conductive material and the contact dielectric film remaining inside the contact trench, the conductive material has a relatively large thickness in a first direction parallel to the upper surface of the semiconductor substrate.

20. The manufacturing method according to claim 2, wherein
the trench portion includes an in-trench dielectric film which covers an inner wall of the trench portion,
the contact dielectric film is thinner than the in-trench dielectric film.
